(19) United States
(12) Patent Application Publication
(10) Pub. No.: US 2026/0025059 A1
(43) Pub. Date: Jan. 22, 2026

(54) GATE DRIVER CIRCUIT, POWER SUPPLY CONTROL CIRCUIT, AND POWER SUPPLY DEVICE

(71) Applicant: ROHM CO., LTD., Kyoto (JP)

(72) Inventors: Takumi FUJIMAKI, Kyoto (JP); Haruka MATSUURA, Kyoto (JP)

(21) Appl. No.: 19/266,377

(22) Filed: Jul. 11, 2025

(30) Foreign Application Priority Data
Jul. 18, 2024 (JP) 2024-114739

(51) Int. Cl. H02M 1/08; H02M 3/156; H03K 17/687

(52) U.S. Cl. CPC H02M 1/08; H02M 3/156; H03K 17/687

(57) ABSTRACT

A gate driver circuit includes: a drive control circuit for receiving a pulse signal and upper and lower voltages, generate a drive signal which drives in a pulse manner between the upper and lower voltages at a period corresponding to the pulse signal, and input the drive signal to a gate of a switch element to be driven to drive and control the switch element; a reference voltage generation circuit for generating a reference voltage; and an upper voltage generation circuit for generating the upper voltage based on the reference voltage with reference to a source voltage generated at a source of the switch element according to a drain current of the switch element. The drive control circuit sets the drive signal to the upper voltage to turn on the switch element to be driven and sets the drive signal to the lower voltage to turn off the switch element.

### CROSS-REFERENCE TO RELATED APPLICATION

The present invention claims priority under 35 U.S.C. § 119 to Japanese Patent Application No. 2024-114739, filed on Jul. 18, 2024, the entire contents of which are incorporated herein by reference.

### TECHNICAL FIELD

The present disclosure relates to a gate driver circuit, a power supply control circuit, and a power supply device.

### BACKGROUND

In the related art, there is a power supply device which generates an output voltage by a switching operation using a switch element. Such a power supply device includes a gate driver circuit which generates a drive signal for driving the switch element.

### BRIEF DESCRIPTION OF DRAWINGS

The accompanying drawings, which are incorporated in and constitute a part of the specification, illustrate embodiments of the present disclosure.

FIG. 1 is a diagram showing a power supply device which is a so-called DC/DC converter.

FIG. 2 is a diagram showing an internal configuration of a high-side regulator.

FIG. 3 is a graph showing a waveform of each voltage of a power supply control device.

FIG. 4 is a graph showing a drain-source current and a drain-source voltage of a switch element.

FIG. 5 is a diagram showing a power supply device which is a so-called DC/DC converter.

FIG. 6 is a diagram showing an internal configuration of a high-side regulator.

FIG. 7 is a graph showing a waveform of each voltage of a power supply control device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Power Supply Device 200Y of Comparative Example>

First, a power supply device 200Y will be described as a comparative example of a power supply device 200X of the present disclosure. Next, matters of the comparative example will be described, and the power supply device 200X of the present disclosure will be described.

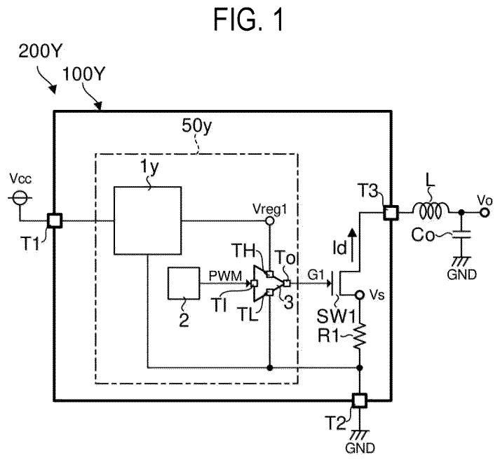

FIG. 1 is a diagram showing the power supply device 200Y. The power supply device 200Y is a so-called DC/DC converter. The power supply device 200Y receives a power supply voltage Vcc, generates an output voltage Vo, and supplies the output voltage Vo to a load (not shown). As shown in FIG. 1, the power supply device 200Y includes a power supply control device 100Y and various discrete components (e.g., an inductor L and a capacitor Co).

The power supply control device 100Y includes a plurality of external terminals (external terminals T1 to T3 in FIG. 1) as a means for establishing an electrical connection with the outside. An application terminal of the power supply voltage Vcc is connected to the external terminal T1. The external terminal T2 is connected to a ground terminal GND. A first terminal of the inductor L is connected to the external terminal T3.

A second terminal of the inductor L is connected to a first terminal of the capacitor C1. A second terminal of the capacitor C1 is connected to the ground terminal. The DC output voltage Vo is generated at a connection node between the inductor L and the capacitor C1. The output voltage Vo is obtained by smoothing a voltage, which is obtained by undergoing a current-voltage conversion by the inductor L, using the capacitor C1.

The power supply control device 100Y includes a gate driver circuit 50y, a switch element SW1, and a sense resistor R1.

The gate driver circuit 50y is configured to generate a drive signal G1. The gate driver circuit 50y includes a high-side regulator 1y, a pulse signal generation circuit 2, and a drive control circuit 3.

The high-side regulator 1y is connected to the external terminals T1 and T2. The high-side regulator 1y receives the power supply voltage Vcc and a ground voltage GND and generates an upper voltage Vreg1 with reference to the ground voltage GND. In the present disclosure, the ground voltage generated at the ground terminal GND is also referred to as the ground voltage GND using the same reference symbol. A detailed configuration of the high-side regulator 1y will be described later.

The pulse signal generation circuit 2 generates a pulse signal PWM which drives in a pulse manner at a predetermined frequency.

The drive control circuit 3 has an input terminal TI, an output terminal TO, an upper power supply terminal TH, and a lower power supply terminal TL. The input terminal TI is connected to the pulse signal generation circuit 2. The input terminal TI receives the pulse signal PWM provided from the pulse signal generation circuit 2. The output terminal TO is connected to a gate terminal of the switch element SW1 to be described later. The output terminal TO is a terminal at which the drive signal G1 to be described later is generated.

The upper power supply terminal TH is connected to the high-side regulator 1y. The upper power supply terminal TH receives the upper voltage Vreg1 from the high-side regulator 1y. The lower power supply terminal TL is connected to the external terminal T2. The lower power supply terminal TL receives the ground voltage GND.

The drive control circuit 3 receives the pulse signal PWM, the upper voltage Vreg1, and the ground voltage and generates the drive signal G1. More specifically, the drive control circuit 3 generates the drive signal G1 which drives in a pulse manner between a high level (corresponding to the upper voltage Vreg1) and a low level (corresponding to the ground voltage GND) so as to be synchronized with a pulse period of the pulse signal PWM.

The switch element SW1 is an enhancement type high electron mobility transistor (Gan-HEMT). The gate terminal of the switch element SW1 is connected to the output terminal of the drive control circuit 3. The drain terminal of the switch element SW1 is connected to the external terminal T3. A source terminal of the switch element SW1 is connected to a first terminal of the sense resistor R1. A second terminal of the sense resistor R1 is connected to the external terminal T2.

The switch element SW1 is controlled to be turned on/off by the drive signal G1. Specifically, when the drive signal G1 is at a high level, the switch element SW1 is turned on. In addition, when the drive signal G1 is at a low level, the switch element SW1 is turned off. Details thereof will be described later.

In the switch element SW1, a channel between the source terminal and the drain terminal is inverted according to a gate-source voltage difference to form an inversion layer (not shown). When the gate-source voltage difference exceeds a predetermined threshold voltage, the formed inversion layer becomes a current path so that the source terminal and the drain terminal are in a conductive state (ON state). Conversely, when the gate-source voltage difference is less than the predetermined threshold voltage, the source terminal and the drain terminal are in a non-conductive state (OFF state).

In the conductive state, as the gate-source voltage difference increases, an ON-resistance of the switch element SW1 decreases. In other words, as the gate-source voltage difference increases, a ratio of a current value of a drain current Id to a voltage value of a source voltage Vs increases. Here, the ratio of the current value of the drain current Id to the voltage value of the source voltage Vs is also referred to as a current capacity of the switch element SW1.

When the switch element SW1 is in the conductive state, the drain current Id flows between the source and drain of the switch element SW1. The drain current Id flows through the inductor L so that the current-voltage conversion is performed. The voltage converted from the drain current Id by the inductor L is smoothed by the capacitor Co to generate the output voltage Vo which is a DC voltage.

When the switch element SW1 is in the conductive state, the source voltage Vs is generated in the switch element SW1 according to the drain current Id. More specifically, the source voltage Vs is determined by the current value of the drain current Id and a resistance value of the sense resistor R1. When the switch element SW1 is in the non-conductive state, the drain current Id does not flow (the current value of the drain current Id is set to 0), and the source voltage Vs is 0 V.

As described above, the sense resistor R1 generates a voltage between two terminals thereof by the drain current Id. By detecting the voltage between the two terminals of the sense resistor R1, it is possible to sense (detect) the current value of the drain current Id. For this reason, the sense resistor R1 may be understood to be disposed to sense the drain current Id.

<Detailed Configuration of High-Side Regulator 1y>

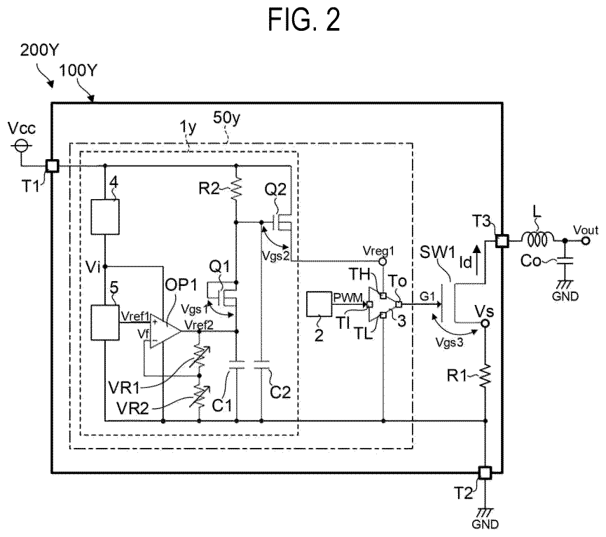

FIG. 2 is a diagram showing an internal configuration of the high-side regulator 1y. As shown in FIG. 2, the high-side regulator 1y includes an internal power supply circuit 4, a reference voltage generation circuit 5, an operational amplifier OP1, transistors Q1 and Q2, variable resistors VR1 and VR2, a resistor R2, and capacitors C1 and C2.

A first terminal of the internal power supply circuit 4 is connected to the external terminal T1, a second terminal thereof is connected to an upper power supply terminal of the operational amplifier OP1, and a third terminal thereof is connected to the reference voltage generation circuit 5. The internal power supply circuit 4 receives the power supply voltage Vcc via the external terminal T1 and generates a predetermined internal voltage Vi. In addition, the internal power supply circuit 4 supplies the internal voltage Vi to each of the reference voltage generation circuit 5 and the operational amplifier OP1.

The reference voltage generation circuit 5 is a band gap type power supply circuit. The reference voltage generation circuit 5 is connected to the internal power supply circuit 4, the ground terminal GND, and a non-inverting input terminal (+) of the operational amplifier OP1. The reference voltage generation circuit 5 receives the internal voltage Vi and generates a first reference voltage Vref1 based on the ground voltage GND. The reference voltage generation circuit 5 supplies the first reference voltage Vref1 to the non-inverting input terminal (+) of the operational amplifier OP1.

An output terminal of the operational amplifier OP1 is fed back to an inverting input terminal (−) via the variable resistor VR1. Specifically, the output terminal of the operational amplifier OP1 is connected to a first terminal of the variable resistor VR1. A second terminal of the variable resistor VR1 is connected to a first terminal of the variable resistor VR2. A second terminal of the variable resistor VR2 is connected to the ground terminal GND.

The variable resistors VR1 and VR2 are connected in series to form a voltage-dividing circuit. A feedback voltage Vf according to a voltage division ratio of the variable resistors VR1 and VR2 is generated at a connection node between the variable resistor VR1 and the variable resistor VR2.

The operational amplifier OP1 controls an output of a second reference voltage Vref2 so that the first reference voltage Vref1 is equal to the feedback voltage Vf (i.e., so that the non-inverting input terminal (+) and the inverting input terminal (−) are imaginarily shorted).

The transistors Q1 and Q2 are N-channel metal-oxide-semiconductor field-effect transistors (MOSFETs). A gate terminal and a drain terminal of the transistor Q1 are connected to each other. That is, the transistor Q1 is a diode-connected transistor. The drain terminal of the transistor Q1 is connected to a gate terminal of the transistor Q2 together with a first terminal of the resistor R2. A source terminal of the transistor Q1 is connected to the first terminal of the capacitor C1 together with the output terminal of the operational amplifier OP1.

A drain terminal of the transistor Q2 is connected to the output terminal of the power supply voltage Vcc together with the first terminal of the resistor R2. A source terminal of the transistor Q2 is connected to the upper power supply terminal of the drive control circuit 3 as the output terminal of the upper voltage Vreg1.

The second terminal of the capacitor C1 is connected to the ground terminal GND together with the second terminal of the sense resistor R1. A first terminal of the capacitor C2 is connected to the gate terminal of the transistor Q2. A second terminal of the capacitor C2 is connected to the ground terminal GND together with the second terminal of the sense resistor R1.

Basically, the transistors Q1 and Q2 are always in an ON state. Further, as described above, the transistor Q1 is in a diode-connected state. Therefore, a gate voltage and a drain voltage of the transistor Q1 are equal to a gate voltage of the transistor Q2.

Here, the gate voltage of the transistor Q1 is a value obtained by subtracting the second reference voltage Vref2 from the gate-source voltage Vgs1 of the transistor Q1. The gate voltage of the transistor Q2 is a value obtained by subtracting the upper voltage Vreg1 from the gate-source voltage Vgs2 of the transistor Q2. Since these two values are equal to each other, the upper voltage Vreg1 is a value obtained by subtracting the gate-source voltage Vgs2 from the sum of the second reference voltage Vref2 and the gate-source voltage Vgs1.

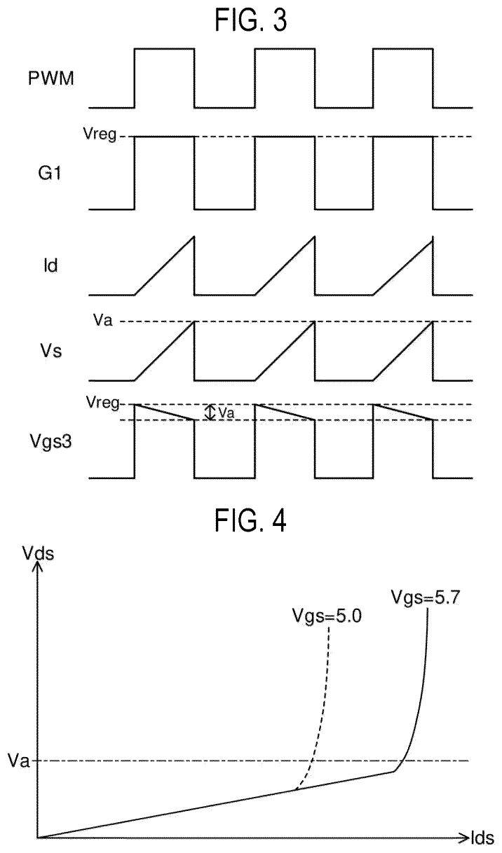

FIG. 3 is a graph showing a waveform of each voltage of the power supply control device 100Y. FIG. 3 shows, from top to bottom, the pulse signal PWM, the drive signal G1, the drain current Id, the source voltage Vs, and the gate-source voltage Vgs3. In FIG. 3, a voltage waveform has a voltage value on the vertical axis, a current waveform has a current value on the vertical axis, and both the voltage waveform and the current waveform have a time axis on the horizontal axis.

As shown in FIG. 3, the pulse signal PWM is a digital signal which changes between two values such as a high level and a low level, with a predetermined period and a predetermined duty ratio. When the pulse signal PWM is at the high level, the drive control circuit 3 takes the upper voltage Vreg1 and outputs the same as the drive signal G1. In addition, when the pulse signal PWM is at the low level, the drive control circuit 3 takes the ground voltage GND and outputs the same as the drive signal G1. Therefore, the drive signal G1 changes between two values such as the high level (a voltage value equivalent to the upper voltage Vreg1) and the low level (a voltage value equivalent to the ground voltage GND), in synchronization with the pulse signal PWM.

When the drive signal G1 rises to the high level, the gate-source voltage Vgs3 also rises in conjunction with the drive signal G1. This turns on the switch element SW1, and the drain current Id starts to flow. Here, as described above, the drain current Id is smoothed by the inductor L and the capacitor Co. Therefore, the value of the drain current Id gradually increases at a predetermined slew rate during the ON period of the switch element SW1.

When the drive signal G1 falls to the low level, the gate-source voltage Vgs3 also falls in conjunction with the drive signal G1. This turns off the switch element SW1 so that the flow of the drain current Id is stopped.

As described above, the source voltage Vs is determined based on the current value of the drain current Id and the resistance value of the sense resistor R1. Therefore, as the value of the drain current Id gradually increases, the source voltage Vs also gradually increases at a slew rate equal to that of the drain current Id.

### <Considerations on Current Capacity of Switch Element SW1>

The upper voltage Vreg1 is maintained at a constant voltage value. Therefore, the gate-source voltage Vgs3 decreases with the increase in the source voltage Vs. Specifically, when the source voltage Vs increases from 0 V to a certain voltage Va during the ON period of the switch element SW1, the gate-source voltage Vgs3 during the same period may be gradually decreased by the voltage Va from the upper voltage Vreg1.

As described above, the gate-source voltage Vgs3 affects the current capacity of the switch element SW1. Therefore, when the gate-source voltage Vgs3 decreases, the current capacity of the switch element SW1 may be decreased. Further, in the case in which the Gan-HEMT is used as the switch element SW1, there are issues as explained below.

### <Considerations on Current Capacity of Gan-HEMT>

General characteristics of the Gan-HEMT are as follows. To increase the current capacity of the Gan-HEMT, the high-level drive signal input to the gate of the Gan-HEMT needs to be set to a predetermined voltage range (hereinafter, also referred to as a “high efficiency range”).

A specific example will be described later. For example, a high efficiency range of the switch element SW1 is assumed to be equal to or more than 5.5 V and less than 6.0 V. An upper limit of the high efficiency range is a rated voltage (gate pressure-resistant voltage) of the switch element SW1. In this case, when the voltage value of the high-level drive signal G1 falls below 5.5 V, the current capacity of the switch element SW1 may be dropped significantly. In addition, when the drive signal G1 exceeds 6.0 V, the current capacity of the switch element SW1 may exceed the rated voltage of the switch element SW1. This may destroy the switch element SW1. Details thereof will be described later.

FIG. 4 is a graph showing the drain-source current Ids and the drain-source voltage Vds of the switch element SW1. In FIG. 4, a state in which the gate-source voltage Vgs3 of the switch element SW1 is 5.0 V (a state in which the drive signal G1 falls outside the high efficiency range) is shown by a broken line. In addition, in FIG. 4, a state in which the gate-source voltage Vgs3 of the switch element SW1 is 5.7 V (a state in which the drive signal G1 falls within the high efficiency range) is shown by a solid line. In this case, an ON-threshold voltage of the switch element SW1 is less than 5.0 V.

As shown in FIG. 4, for example, when the drain-source voltage Vds is a predetermined voltage Vb, the current value of the drain-source current Ids is larger when the gate-source voltage Vgs3 is 5.7 V than when the gate-source voltage Vgs3 is 5.0 V. In this way, when the gate-source voltage Vgs3 of the switch element SW1 is set to a value in the high efficiency range (in this example, equal to or more than 5.5 V and less than 6.0 V), the current capability of the switch element SW1 is properly exhibited.

Therefore, the gate driver circuit 50y sets the voltage value of the high-level drive signal G1 (the voltage value of the upper voltage Vreg1) to a value in the high efficiency range. At this time, the gate driver circuit 50y generates the upper voltage Vreg1 as a constant voltage with reference to the ground terminal GND. Then, as described above, when the gate-source voltage Vgs3 decreases with the increase in the drain current Id, the voltage value of the gate-source voltage Vgs3 may fall outside the high efficiency range.

To address this issue, a gate driver circuit 50x according to the present disclosure is configured to be capable of suppressing a decrease in the current capability of the switch element SW1. The gate driver circuit 50x, a power supply control device 100X, and a power supply device 200X according to an embodiment of the present disclosure will be described in detail below. The gate driver circuit 50x, the power supply control device 100X, and the power supply device 200X according to an embodiment of the present disclosure include configurations common to the gate driver circuit 50y, the power supply control device 100Y, and the power supply control device 100Y described as above. Therefore, such common configurations will be denoted by the same reference numerals, and descriptions thereof will be omitted.

### <Power Supply Device 200X According to Embodiment of Present Disclosure>

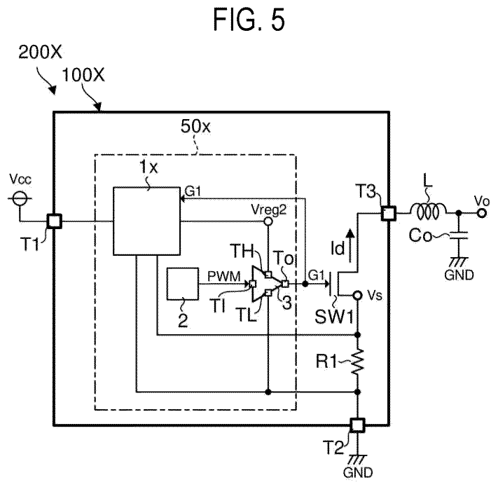

FIG. 5 is a diagram showing the power supply device 200X. The power supply device 200X is a so-called DC/DC converter. The power supply device 200X receives a power supply voltage Vcc, generates an output voltage Vo, and supplies the output voltage Vo to a load (not shown). As shown in FIG. 5, the power supply device 200X includes a power supply control device 100X and various discrete components (e.g., an inductor L and a capacitor Co).

The power supply control device 100X has a plurality of external terminals (external terminals T1 to T3 in FIG. 1) as a means for establishing an electrical connection with the outside. The external terminal T1 is connected to the application terminal of the power supply voltage Vcc. The external terminal T2 is connected to the ground terminal GND. The first terminal of the inductor L is connected to the external terminal T3.

The power supply control device 100X has a switch element SW1 and a sense resistor R1, which are the same as those described above. Further, the power supply control device 100X includes a gate driver circuit 50x.

The gate driver circuit 50x is configured to generate a drive signal G1. The gate driver circuit 50x has a pulse signal generation circuit 2 and a drive control circuit 3, which are the same as those described above. Further, the gate driver circuit 50x includes a high-side regulator 1x.

The high-side regulator 1x is connected to the external terminal T1, the external terminal T2, the output terminal TO, and the source terminal of the switch element SW1.

The high-side regulator 1x receives the power supply voltage Vcc, a source voltage Vs, and the drive signal G1, generates an upper voltage Vreg2 with reference to the source voltage Vs, and inputs the same to an upper power supply terminal TH. That is, as described above, when the source voltage Vs rises, the upper voltage Vreg2 also rises in conjunction with the source voltage Vs. A rise rate (slew rate) of the upper voltage Vreg2 at this time corresponds to a rise rate (slew rate) of the source voltage Vs.

Thus, even if the source voltage Vs rises during the ON period of the switch element SW1, the drive signal G1 (the upper voltage Vreg2) also rises at the same time. As a result, the gate-source voltage Vgs3 is maintained constant during the ON period of the switch element SW1. Therefore, the current capacity of the switch element SW1 may be prevented from decreasing. A detailed configuration of the high-side regulator 1x will be described below.

<Detailed Configuration of High-Side Regulator 1x>

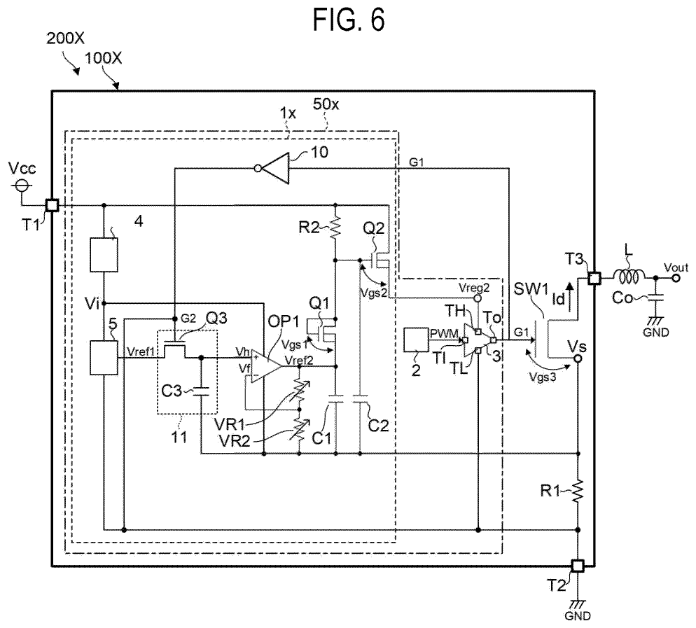

FIG. 6 shows an internal configuration of the high-side regulator 1x. As shown in FIG. 6, the high-side regulator 1x includes an internal power supply circuit 4, a reference voltage generation circuit 5, an operational amplifier OP1, transistors Q1 and Q2, variable resistors VR1 and VR2, a resistor R2, and capacitors C1 and C2, which are the same as those described above. A lower power supply terminal of the operational amplifier OP1, a second terminal of the variable resistor VR2, and second terminals of the capacitors C1 and C2 are connected to the ground terminal GND.

Further, the high-side regulator 1x includes an inverter 10 and a sample/hold circuit 11.

An input terminal of the inverter 10 is connected to the output terminal TO. An output terminal of the inverter 10 is connected to the sample/hold circuit 11 (more specifically, a gate terminal of a transistor Q3 to be described later).

The inverter 10 receives the drive signal G1 and supplies a drive signal G2, which is logically inverted from the drive signal G1, to the sample/hold circuit 11 (more specifically, the gate terminal of the transistor Q3). Specifically, when the drive signal G1 is at a high level, the drive signal G2 is at a low level. Conversely, when the drive signal G1 is at a low level, the drive signal G2 is at a high level.

The sample/hold circuit 11 is connected to the reference voltage generation circuit 5, the inverter 10, the operational amplifier OP1, and a source terminal of the switch element SW1. The sample/hold circuit 11 receives a first reference voltage Vref1 and the drive signal G2, generates a hold voltage Vh, and inputs the same to a non-inverting input terminal (+) of the operational amplifier OP1. Specific details thereof will be described later.

The sample/hold circuit 11 includes the transistor Q3 and a capacitor C3. The transistor Q3 is an N-channel MOSFET. A drain terminal of the transistor Q3 is connected to the reference voltage generation circuit 5. A source terminal of the transistor Q3 is connected to an inverting input terminal of the operational amplifier OP1 together with the first terminal of the capacitor C3. As described above, the gate terminal of the transistor Q3 is connected to the output terminal of the inverter 10. The second terminal of the capacitor C3 is connected to the source terminal of the switch element SW1.

The transistor Q3 is controlled to be turned on/off by the drive signal G2. Specifically, when the drive signal G2 is at the high level, a channel inversion layer is formed between the source terminal and the drain terminal. Such an inversion layer becomes a current path so that the transistor Q3 is in a conductive state (ON state). Conversely, when the drive signal G2 is at the low level, the channel inversion layer disappears between the source terminal and the drain terminal so that the transistor Q3 is in a non-conductive state (OFF state).

The sample/hold circuit 11 samples (acquires) the first reference voltage Vref1 when the drive signal G1 is at the low level, and holds (retains) the sampled first reference voltage Vref1 when the drive signal G1 is at the high level. Specific details thereof will be described later.

When the drive signal G1 is at the low level, the drive signal G2 is at the high level. At this time, the transistor Q3 is turned on, and the first reference voltage Vref1 is supplied to the non-inverting input terminal (+) of the operational amplifier OP1 and the first terminal of the capacitor C3. Then, charges corresponding to a potential difference between the source voltage Vs and the first reference voltage Vref1 are accumulated in the capacitor C3. In other words, the capacitor C3 samples the first reference voltage Vref1.

When the drive signal G1 is at the high level, the drive signal G2 is at the low level. At this time, the transistor Q3 is turned off. At this time, the charges corresponding to the potential difference between the source voltage Vs and the first reference voltage Vref1 are accumulated in the capacitor C3 through the sampling operation. Therefore, the hold voltage Vh is held at a voltage value equivalent to the first reference voltage Vref1 with reference to the source voltage Vs.

During the ON period of the switch element SW1 (i.e., when the drive signal G1 is at the high level), a second reference voltage Vref2 is generated by the operational amplifier OP1 and the variable resistors VR1 and VR2 based on the first reference voltage Vref1 held with reference to the source voltage Vs. In other words, the second reference voltage Vref2 is a voltage with reference to the source voltage Vs.

In addition, as described above, second terminals of the capacitors C1 and C2 are connected to the source terminal of the switch element SW1. Therefore, each of a gate-source voltage Vgs1 and a gate-source voltage Vgs2 becomes a voltage with reference to the source voltage Vs.

The upper voltage Vreg2 is a value obtained by subtracting the gate-source voltage Vgs2 from the sum of the second reference voltage Vref2 and the gate-source voltage Vgs1. Since the second reference voltage Vref2, the gate-source voltage Vgs1, and the gate-source voltage Vgs2 are voltages with reference to the source voltage Vs, the upper voltage Vreg2 is also a voltage with reference to the source voltage Vs.

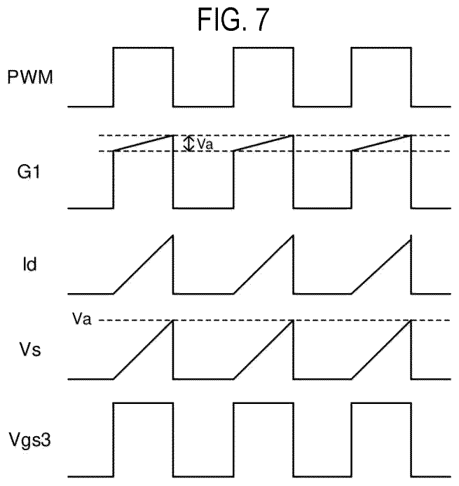

FIG. 7 is a graph showing a waveform of each voltage of the power supply control device 100X. FIG. 7 shows, from top to bottom, the pulse signal PWM, the drive signal G1, the drain current Id, the source voltage Vs, and the gate-source voltage Vgs3. In FIG. 7, a voltage waveform has a voltage value on the vertical axis, a current waveform has a current value on the vertical axis, and both the voltage waveform and the current waveform have a time axis on the horizontal axis.

As shown in FIG. 7, when the pulse signal PWM is at the high level, the drive control circuit 3 takes the upper voltage Vreg2 and outputs the same as the drive signal G1. In addition, when the pulse signal PWM is at the low level, the drive control circuit 3 takes the ground voltage GND and outputs the same as the drive signal G1.

When the drive signal G1 rises to a high level, the drain current Id flows so as to gradually rise at a predetermined slew rate as described above. In response to this, the source voltage Vs also gradually rises at an equivalent slew rate.

Here, the upper voltage Vreg2 is a voltage with reference to the source voltage Vs. More specifically, the upper voltage Vreg2 is generated by the high-side regulator 1x based on the power supply voltage Vcc with reference to the source voltage Vs. Therefore, when the source voltage Vs rises, the upper voltage Vreg2 also rises with the rise in the source voltage Vs. An amount of rise in the upper voltage Vreg2 at this time corresponds to an amount of rise in the source voltage Vs.

During the ON period of the switch element SW1, since the drive signal G1 corresponds to the upper voltage Vreg2, both the source voltage Vs and the drive signal G1 rise equally. For example, as shown in FIG. 7, when the source voltage Vs rises by a predetermined voltage Va during the ON period of the switch element SW1, the drive signal G1 also rises by the predetermined voltage Va during the same period. Therefore, even if the source voltage Vs rises during the ON period of the switch element SW1, the gate-source voltage Vgs3 is kept constant without decreasing.

### Modifications

The present disclosure is not limited to the above-described embodiments, and various modifications are possible without departing from the scope and spirit of the present disclosure. For example, the switch element SW1 is an enhancement type Gan-HEMT but is not limited thereto. For example, the switch element SW1 may be a depression type Gan-HEMT.

In addition, the switch element SW1 may be a general MOSFET. Even in this case, the reduction in the current capacity of the switch element SW1 may be suppressed as described above. As described above, in the Gan-HEMT, the drive signal G1 in the high efficiency range may be preferably generated. Thus, by employing the configuration of the present disclosure, it is possible to more effectively suppress the reduction in the current capability.

In addition, although the power supply control device 100X has been described as including the sense resistor R1, it may not include the sense resistor R1. For example, the sense resistor R1 may be externally connected between the switch element SW1 and the ground terminal GND by being externally attached to the external terminal T2 of the power supply control device 100X. In this case, the effect of suppressing the reduction in the current capability of the switch element SW1 described above may be obtained.

In addition, the sense resistor R1 may be a resistor, or a semiconductor element having a predetermined resistance value when both terminals are in a conductive state, such as a MOSFET in the diode-connected state.

### SUPPLEMENTARY NOTES

A gate driver circuit 50x disclosed herein has a first configuration including a drive control circuit 3 configured to receive a pulse signal PWM, an upper voltage Vreg2, and a lower voltage GND, generate a drive signal G1 which drives in a pulse manner between the upper voltage Vreg2 and the lower voltage GND at a period corresponding to the pulse signal PWM, and input the drive signal G1 to a gate of a switch element SW1 to be driven to drive and control the switch element SW1, a reference voltage generation circuit 5 (OP1, VR1, and VR2) configured to generate a reference voltage Vref1 (or Vref2), and an upper voltage generation circuit 1x configured to generate the upper voltage Vreg2 based on the reference voltage Vref1 (or Vref2) with reference to a source voltage Vs, which is generated at a source of the switch element SW1 according to a drain current Id of the switch element SW1. The drive control circuit 3 sets the drive signal G1 to the upper voltage Vreg2 to turn on the switch element SW1 to be driven, and sets the drive signal G1 to the lower voltage GND to turn off the switch element SW1.

The gate driver circuit 50x of the first configuration has a second configuration including a sample/hold circuit 11 configured to sample the reference voltage Vref1 (or Vref2) with reference to the source voltage Vs when the drive signal G1 is the lower voltage GND, and to hold the sampled reference voltage Vref1 (or Vref2) when the drive signal G1 is the upper voltage Vreg2. The upper voltage generation circuit 1x generates the upper voltage Vreg2 based on the sampled reference voltage Vref1 (or Vref2) with reference to the source voltage Vs.

A power supply control device 100X disclosed herein has a third configuration including the gate driver circuit 50x of the first or second configuration and the switch element SW1.

The power supply control device 100X of the third configuration has a fourth configuration in which the switch element SW1 is a Gan-HEMT.

The power supply control device 100X of the third or fourth configuration has a fifth configuration including a semiconductor element R1 having a first terminal connected to the source of the switch element SW1 and a second terminal connected to an application terminal of the lower voltage GND, and including a resistor through which a current flows to generate the source voltage Vs between the first terminal and the second terminal.

A power supply device 200X disclosed herein has a sixth configuration including a power supply control device 100X of any one of the third to fifth configurations and a current-voltage conversion circuit L (and Co) connected to a drain of the switch element SW1 and configured to generate an output voltage Vo according to the drain current Id.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gate driver circuit comprising:
a drive control circuit configured to receive a pulse signal, an upper voltage, and a lower voltage, generate a drive signal which drives in a pulse manner between the upper voltage and the lower voltage at a period corresponding to the pulse signal, and input the drive signal to a gate of a switch element to be driven to drive and control the switch element;
a reference voltage generation circuit configured to generate a reference voltage; and
an upper voltage generation circuit configured to generate the upper voltage based on the reference voltage with reference to a source voltage generated at a source of the switch element according to a drain current of the switch element,
wherein the drive control circuit sets the drive signal to the upper voltage to turn on the switch element to be driven and sets the drive signal to the lower voltage to turn off the switch element.

2. The gate driver circuit of claim 1, further comprising:
a sample/hold circuit configured to sample the reference voltage with reference to the source voltage when the drive signal is the lower voltage, and to hold the sampled reference voltage when the drive signal is the upper voltage,
wherein the upper voltage generation circuit generates the upper voltage based on the sampled reference voltage with reference to the source voltage.

3. A power supply control device comprising:
the gate driver circuit of claim 1; and
the switch element.

4. The power supply control device of claim 3, wherein the switch element is a Gan-HEMT.

5. The power supply control device of claim 3, further comprising:
a semiconductor element having a first terminal connected to the source of the switch element and a second terminal connected to an application terminal of the lower voltage, and including a resistor through which a current flows to generate the source voltage between the first terminal and the second terminal.

6. A power supply device comprising:
the power supply control device of claim 3; and
a current-voltage conversion circuit connected to a drain of the switch element and configured to generate an output voltage according to the drain current.
